(19) United States
(12) Patent Application Publication
(10) Pub. No.: US 2021/0005757 A1
(43) Pub. Date: Jan. 7, 2021

(54) METHOD OF MANUFACTURING A THIN FILM TRANSISTOR SUBSTRATE AND THIN FILM TRANSISTOR SUBSTRATE

(71) Applicant: Wuhan China Star Optoelectronics Semiconductor Display Technology Co., Ltd., Wuhan, Hubei (CN)

(72) Inventors: Zhenyu ZHAO, Wuhan, Hubei (CN); Wei Li, Wuhan, Hubei (CN)

(21) Appl. No.: 16/344,099

(22) PCT Filed: Dec. 11, 2018
(86) PCT No.: PCT/CN2018/120417

§ 371 Date: Apr. 23, 2019

(30) Foreign Application Priority Data
Dec. 3, 2018 (CN) 201811468004.7

(51) Int. Cl. H01L 29/786; H01L 27/12; H01L 21/02; H01L 21/383; H01L 29/66

(52) U.S. Cl. CPC H01L 29/78645; H01L 27/1225; H01L 29/78618; H01L 29/7869; H01L 27/127; H01L 29/66969; H01L 21/0217; H01L 21/02274; H01L 21/02565; H01L 21/02623; H01L 21/383; H01L 21/02164

(57) ABSTRACT

A method of manufacturing a thin film transistor (TFT) substrate and a TFT substrate. The method of manufacturing the TFT substrate adopts a first gate and a second gate to form a double gate structure, and uses a silicon nitride layer to form a etch stop layer. When depositing the silicon nitride layer of the etch stop layer, hydrogen atoms in the silicon nitride layer diffuse into the active layer to form a doping in the active layer. The hydrogen atoms provide a large amount of electrons as a donor, which increases an electron mobility of a channel region with low impedance and further reduces the impedance. Thus, a TFT channel series structure is formed in the channel region. A double TFT structure is realized by an ion diffusion doping, which saves costs and effectively saves space and optimizes a spatial layout in practical use.

### FIELD OF INVENTION

The present disclosure relates to the field of display technologies, and more particularly to a method of manufacturing a thin film transistor (TFT) substrate and a TFT substrate.

### BACKGROUND OF INVENTION

In the field of display technologies, flat panel displays such as liquid crystal displays (LCD) and organic light emitting diode (OLED) displays have gradually replaced (cathode ray tube) CRT displays, and are widely used in LCD televisions (TVs), mobile phones, personal digital assistants, digital cameras, computer screens, or laptop computer screens.

Display panel is an important part of the LCD and the OLED. Both LCD display panel and OLED display panel usually have a thin film transistor (TFT) substrate. Taking the LCD display panel as an example, it is mainly composed of a TFT substrate, a color filter (CF) substrate, and a liquid crystal layer between the TFT substrate and the CF substrate. The working principle of the LCD display panel is to control a rotation of liquid crystal molecules in the liquid crystal layer by applying a driving voltage on the TFT substrate and the CF substrate, and refract light of a backlight module to generate a picture.

At present, current TFT substrates are mainly classified into coplanar type, etch stop layer (ESL) type, back channel etch (BCE) type, and the like according to a structure type thereof.

Indium gallium zinc oxide (IGZO) has become a research hotspot in the field of TFT technologies due to its high mobility, suitability for large-sized production, and easy conversion from amorphous silicon (a-Si) process. However, an active layer in an IGZO-TFT is very sensitive to process and environment, therefore the IGZO-TFT usually adopts a structure of the ESL type. The active layer of IGZO is protected by the ESL and adding a mask, but this is not conducive to a reduction of the TFT process cost. In addition, due to a stack between a source/drain (SD) and the ESL, a channel size of the TFT is larger, which results in a decrease of conductivity of the TFT.

Referring to FIG. 1, a current ESL TFT substrate includes a substrate 100, a gate 200, a gate insulating layer 300, an oxide semiconductor layer 400, an etch stop layer 500, a source 610, and a drain 620 sequentially disposed on the substrate 100. The source 610 and the drain 620 contact the oxide semiconductor layer 400 through a first via 510 and a second via 520 respectively.

The ESL TFT substrate illustrated in FIG. 1 adopts the etch stop layer 500 to avoid damage to a channel, however, a channel length of the TFT increases with an addition of the etch stop layer 500. In a large-sized OLED display panel, an oxide semiconductor material such as IGZO/IGSO (indium gallium selenide) is generally used as a channel substrate because it has a high electron mobility and is suitable for large-sized productions. In order to obtain a higher resolution, a larger opening ratio, and a lower power consumption, a panel is required to obtain a larger OLED driving current at a lower driving turn-on voltage. In general, a higher drain current (Ids) can be obtained by shortening the channel length of the TFT. However, considering an actual process capability, shortening the channel length of the TFT is strictly limited, which may not significantly improve the current driving capability. Therefore, the current driving capability of the large-sized OLED display panel may not be improved by shortening the channel length of the TFT through the process, which needs to be improved urgently.

### SUMMARY OF INVENTION

The present disclosure provides a method of manufacturing a thin film transistor (TFT) substrate, which adopts a double gate structure and forms a TFT channel series structure in a channel region by diffusing and doping hydrogen atoms in a silicon nitride layer, so as to reduce impedance of both sides of a channel, short a channel length, realize a double TFT structure, save costs, and effectively saves space and optimizes a spatial layout in practical use.

The present disclosure provides a thin film transistor (TFT) substrate, which adopts a double gate structure and forms a TFT channel series structure in a channel region by diffusing and doping hydrogen atoms in a silicon nitride layer, so as to reduce impedance of both sides of a channel, short a channel length, realize a double TFT structure, save costs, and effectively save spaces and optimizes a spatial layout in practical use.

In order to solve the above issues, the present disclosure provides a method of manufacturing a TFT substrate. The method includes:

a step S1 of providing a substrate, forming a first gate and a second gate spaced apart from each other on the substrate, depositing a gate insulating layer on the first gate, the second gate, and the substrate, and depositing and patterning to form an active layer on the gate insulating layer corresponding to the first gate and the second gate;

a step S2 of depositing an etch stop layer on the active layer and the gate insulating layer, the etch stop layer comprising a silicon nitride layer, when depositing the silicon nitride layer of the etch stop layer, hydrogen atoms in the silicon nitride layer diffuse into the active layer, so as to reduce impedance of the active layer; and

a step S3 of depositing and patterning to form a source and a drain on the etch stop layer.

In an embodiment of the present disclosure, in the step S2, the silicon nitride layer of the etch stop layer is deposited by a plasma chemical vapor deposition.

In an embodiment of the present disclosure, in the step S1, the active layer is deposited by electroplating and splashing, and a material of the active layer includes a metal oxide semiconductor.

In an embodiment of the present disclosure, the step S1 further includes performing a plasma doping treatment on both sides of the active layer, such that a conductivity of both sides of the active layer is enhanced to form a source contact region and a drain contact region at both ends of the active layer, and a region between the source contact region and the drain contact region is formed as a channel region;

the step S2 further includes patterning the etch stop layer, and the etch stop layer forms a first via and a second via respectively over the source contact region and the drain contact region of the active layer; and

in the step S3, the source and the drain contact the source contact region and the drain contact region through the first via and the second via respectively.

In an embodiment of the present disclosure, the etch stop layer further includes a silicon oxide layer between the silicon nitride layer and the active layer.

In an embodiment of the present disclosure, when the TFT substrate is in use, voltages on the first gate and the second gate are independently controlled.

The present disclosure further provides a thin film transistor (TFT) substrate. The TFT substrate includes a substrate, a first gate and a second gate spaced apart from each other on the substrate, a gate insulating layer on the first gate, the second gate, and the substrate, an active layer disposed on the gate insulating layer corresponding to the first gate and the second gate, an etch stop layer disposed on the active layer, and a source and a drain disposed on the etch barrier layer. The etch stop layer includes a silicon nitride layer, and hydrogen atoms in the silicon nitride layer diffuse into the active layer, so as to reduce impedance of the active layer.

In the embodiments of the present disclosure, a material of the active layer is a metal oxide semiconductor, both sides of the active layer are respectively a source contact region and a drain contact region which are enhanced in a conductivity by plasma doping treatment, and a region between the source contact region and the drain contact region is formed as a channel region, and the etch stop layer is respectively provided with a first via and a second via respectively over the source contact region and the drain contact region of the active layer, and the source and the drain contact the source contact region and the drain contact region through the first via and the second via respectively.

In the embodiments of the present disclosure, the etch stop layer further includes a silicon oxide layer between the silicon nitride layer and the active layer.

In the embodiments of the present disclosure, when the TFT substrate is in use, voltages on the first gate and the second gate are independently controlled.

In the method of manufacturing the TFT substrate of the embodiment of the present disclosure, the first gate and the second gate are formed on the substrate and are spaced apart from each other, and the first gate and the second gate form a double gate structure. Then the gate insulating layer, the active layer, the etch stop layer, the source, and the drain are sequentially formed. The etch stop layer includes the silicon nitride layer. When depositing the silicon nitride layer of the etch stop layer, hydrogen atoms in the silicon nitride layer diffuse into the active layer to form a doping in the active layer. Hydrogen atoms provide a large amount of electrons as a donor, which increases an electron mobility of the channel region with low impedance and further reduces the impedance. Thus, the TFT channel series structure is formed in the channel region, which reduces the impedance of both sides of the channel, shortens the channel length, improves the electron mobility, and reduces a power consumption. Without changing a yellow light processing equipment, the double TFT structure is realized by an ion diffusion doping, which saves costs and effectively saves space and optimizes a spatial layout in practical use. The TFT substrate of the present disclosure adopts the double gate structure and forms the TFT channel series structure in the channel region by diffusing and doping hydrogen atoms in the silicon nitride layer, so as to reduce the impedance of both sides of the channel, short the channel length, improve the electron mobility and reduce the power consumption. Without changing the yellow light processing equipment, the double TFT structure is realized by the ion diffusion doping, which saves costs and effectively saves space and optimizes a spatial layout in practical use.

### DESCRIPTION OF DRAWINGS

For a better understanding of the features and technical contents of the present disclosure, please refer to the following detailed description and figures of the present disclosure. However, the figures are only for reference and illustration, and are not intended to limit the present disclosure.

Combined with the following attached figures, by detailed description of the specific embodiments of the present disclosure, the technical solution and other beneficial performances of the present disclosure will be obvious.

FIG. 1 is a schematic structural diagram of a current ESL type thin film transistor (TFT) substrate.

FIG. 2 is a flowchart of a method of manufacturing a TFT substrate according to an embodiment of the present disclosure.

FIG. 3 is a schematic diagram of step S1 of a method of manufacturing a TFT substrate according to an embodiment of the present disclosure.

FIG. 4 is a schematic diagram of a step S2 of a method of manufacturing a TFT substrate according to an embodiment of the present disclosure.

FIG. 5 is a schematic diagram of step S3 of a method of manufacturing a TFT substrate and a schematic structural diagram of a TFT substrate according to an embodiment of the present disclosure.

FIG. 6 is a schematic overhead diagram of a TFT substrate according to an embodiment of the present disclosure.

FIG. 7 is a circuit diagram of a TFT substrate according to an embodiment of the present disclosure.

### DETAILED DESCRIPTION OF PREFERRED EMBODIMENTS

In order to further clarity the technical means and performances of the present disclosure, the following is described in detail in connection with the embodiments of the present disclosure and the accompanying figures.

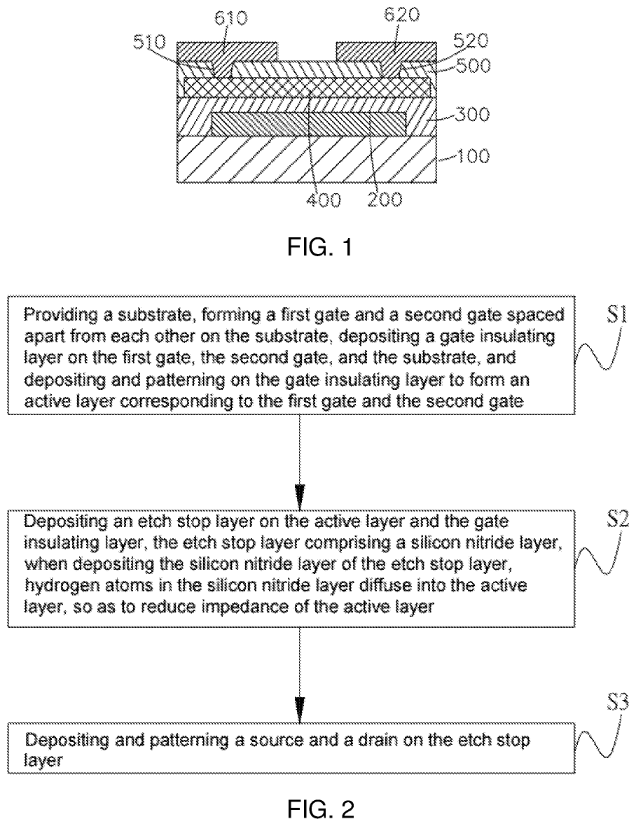

Referring to FIG. 1, an embodiment of the present disclosure provides a method of manufacturing a thin film transistor (TFT) substrate. The method includes the following steps:

Referring to FIG. 2, in a step S1, provide a substrate 10 and form a first gate 21 and a second gate 22 spaced apart from each other on the substrate 10. Deposit a gate insulating layer 30 on the first gate 21, the second gate 22, and the substrate 10. Deposit and pattern to form an active layer 40 on the gate insulating layer 30 corresponding to the first gate 21 and the second gate 22. Perform a plasma doping treatment on both sides of the active layer 40, such that a conductivity on the both sides of the active layer 40 is enhanced to form a source contact region 41 and a drain contact region 42 at both ends of the active layer 40, and a region between the source contact region 41 and the drain contact region 42 is formed as a channel region 43.

In details, materials of the first gate 21 and the second gate 22 include metal materials, such as one or more alloys of molybdenum, aluminum, copper and titanium.

In details, in the step S1, patterning to form the first gate 21, the second gate 22, and the active layer 40 includes photoresist coating, exposure, development, etching, and photoresist removal. The etching of the first gate 21 and the second gate 22 is wet etching, and the etching of the active layer 40 is dry etching.

In details, the material of the active layer 40 formed in the step S1 includes an indium gallium zinc oxide, and can also be a metal oxide semiconductor material such as an indium gallium selenium oxide.

In details, materials of the gate insulating layer 30 include one or a combination of silicon oxide (SiOx) and silicon nitride (SiNx). Preferably, the materials of the gate insulating layer 30 include a silicon oxide.

In details, in the step S1, the gate insulating layer 30 is deposited by a chemical vapor deposition (CVD).

In details, the active layer 40 is deposited by electroplating and splashing.

In details, perform a N-type plasma doping treatment on the both sides of the active layer 40, that is, the source contact region 41 and the drain contact region 42 are both n+IGZO regions which are conductive by the N-type plasma doping treatment.

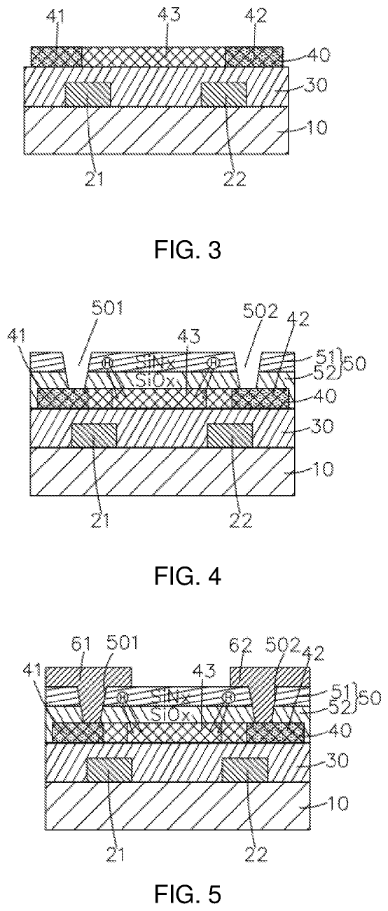

Referring to FIG. 3, in a step S2, deposit the etch stop layer 50 on the active layer 40 and the gate insulating layer 30. The etch stop layer 50 includes a silicon nitride layer 51. When depositing the silicon nitride layer 51 of the etch stop layer 50, hydrogen atoms in the silicon nitride layer 51 diffuse into the active layer 40 so as to reduce impedance of the active layer 40.

In details, the silicon nitride layer 51 of the etch stop layer 50 is deposited by a plasma chemical vapor deposition (PECVD). In this process, the hydrogen atoms in the silicon nitride layer 51 diffuse into the active layer 40. The hydrogen atoms provide a large amount of electrons as a donor, which increases an electron mobility of the channel region 43 with low impedance and further reduces the impedance. Thus, a TFT channel series structure is formed in the channel region 43, which reduces a channel impedance of the first gate 21 and the second gate 22 on the both sides, and shortens a channel length.

In details, the step S2 further includes patterning the etch stop layer 50, and the etch stop layer 50 forms a first via 501 and a second via 502 respectively over the source contact region 41 and the drain contact region 42 of the active layer 40.

In details, the etch stop layer 50 further includes a silicon oxide layer 52 between the silicon nitride layer 51 and the active layer 40.

Referring to FIG. 4, in a step S3, deposit and pattern a source 61 and a drain 62 on the etch stop layer 50. The source 61 and the drain 62 contact the source contact region 41 and the drain contact region 42 through the first via 501 and the second via 502 respectively.

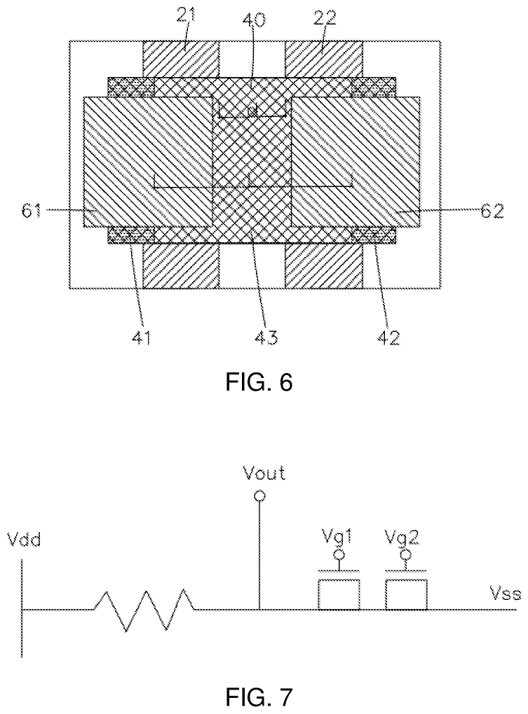

In the method of manufacturing a TFT substrate of the embodiment present disclosure, firstly the first gate 21 and the second gate 22 are formed on the substrate 10 and are spaced apart from each other, and the first gate 21 and the second gate 22 form a double gate structure. Then the gate insulating layer 30, the active layer 40, the etch stop layer 50, the source 61 and the drain 62 are sequentially formed. The etch stop layer 50 includes the silicon nitride layer 51. When depositing the silicon nitride layer 51 of the etch stop layer 50, the hydrogen atoms in the silicon nitride layer 51 diffuse into the active layer 40 and form a doping in the active layer 40. The hydrogen atoms provide a large amount of electrons as a donor, which increases the electron mobility of the channel region 43 with low impedance and further reduces the impedance. Thus, a TFT channel series structure is formed in the channel region 43, which reduces the impedance of the both sides of the channel. Referring to FIG. 6, the channel length is shortened, the electron mobility is improved, and the power consumption is reduced. L is an original channel length, D is an equivalent channel length after adding a double TFT structure. Referring to FIG. 7, without changing a yellow light processing equipment, the double TFT structure is realized by an ion diffusion doping, which saves costs. In addition, a first voltage Vg1 and a second voltage Vg2 are independently controlled, this is, the double TFT structure is independently controlled, which saves costs and effectively save spaces and optimizes a spatial layout in practical use.

Referring to FIG. 5, on the basis of the method of manufacturing a TFT substrate above, the embodiment of the present disclosure further provides a TFT substrate including a substrate 10, a first gate 21 and a second gate 22 spaced apart from each other on the substrate 10, a gate insulating layer 30 on the first gate 21, the second gate 22, and the substrate 10, an active layer 40 disposed on the gate insulating layer 30 and corresponding to the first gate 21 and the second gate 22, an etch stop layer 50 on the active layer 40, and a source 61 and a drain 62 on the etch stop layer 50.

A material of the active layer 40 is a metal oxide semiconductor. Both sides of the active layer 40 are respectively a source contact region 41 and a drain contact region 42 which are enhanced in a conductivity by a plasma doping treatment, and a region between the source contact region 41 and the drain contact region 42 is formed as a channel region 43.

The etch stop layer 50 is respectively provided with a first via 501 and a second via 502 respectively over the source contact region 41 and the drain contact region 42 of the active layer 40, and the source 61 and the drain 62 contact the source contact region 41 and the drain contact region 42 through the first via 501 and the second via 502 respectively.

The etch stop layer 50 includes a silicon nitride layer 51. Hydrogen atoms in the silicon nitride layer 51 diffuse into the active layer 40 to form a doping in the active layer 40. The hydrogen atoms provide a large amount of electrons as a donor, which increases an electron mobility of the channel region 43 with low impedance and further reduces the impedance. Referring to FIG. 6, a TFT channel series structure is formed in the channel region 43, which reduces the channel impedance corresponding to the first gate 21 and the second gate 22, and shortens a channel length. L is the original channel length, D is the equivalent channel length after adding a double TFT structure.

In details, a material of the active layer 40 is the metal oxide semiconductor, preferably IGZO.

The etch stop layer 50 further includes a silicon oxide layer 52 between the silicon nitride layer 51 and the active layer 52.

In details, a N-type plasma doping treatment is performed to both side of the active layer 40, that is, the source contact region 41 and the drain contact region 42 are both n+IGZO regions which are conductive by a N-type plasma doping.

In details, materials of the first gate 21 and the second gate 22 are metal materials, such as one or more alloys of molybdenum, aluminum, copper and titanium.

The TFT substrate of the embodiment of the present disclosure adopts the first gate 21 and the second gate 22 to form a double gate structure, and the silicon nitride layer 51 is disposed on the etch stop layer 50. When depositing the silicon nitride layer 51 of the etch stop layer 50, the hydrogen atoms in the silicon nitride layer 51 diffuse into the active layer 40 and form a doping in the active layer 40. The hydrogen atoms provide a large amount of electrons as a donor, which increases the electron mobility of the channel region 43 with low impedance, and further reduces the impedance. Thus, the TFT channel series structure is formed in the channel region 43, which reduces the impedance of both sides of the channel, shortens the channel length, improves the electron mobility, and reduces the power consumption. D is the equivalent channel length after adding the double TFT structure. Without changing a yellow light processing equipment, the double TFT structure is realized by an ion diffusion doping, which saves costs. In addition, the first voltage Vg1 and the second voltage Vg2 are independently controlled, this is, the double TFT structure is independently controlled, which saves costs and effectively saves space and optimizes a spatial layout in practical use. Table 1 below is a control logic table for controlling on/off a double channel of the TFT substrate of the present disclosure.

TABLE 1

| | |
|---|---|
| Input | Output |

| Vg1 | Vg2 | Vout |
|---|---|---|
| H | H | H |
| H | L | L |
| L | H | L |
| L | L | L |

In summary , in the method of manufacturing the TFT substrate of the embodiment of the present disclosure, the first gate and the second gate are formed on the substrate and are spaced apart from each other, and the first gate and the second gate form the double gate structure. Then the gate insulating layer, the active layer, the etch stop layer, the source, and the drain are sequentially formed. The etch stop layer includes the silicon nitride layer. When depositing the silicon nitride layer of the etch stop layer, the hydrogen atoms in the silicon nitride layer diffuse into the active layer, so as to form a doping in the active layer. The hydrogen atoms provide a large amount of electrons as a donor, which increases the electron mobility of the channel region with low impedance and further reduces the impedance. Thus, the TFT channel series structure is formed in the channel region, which reduces the impedance of both sides of the channel, shortens the channel length, improves the electron mobility, and reduces the power consumption. Without changing the yellow light processing equipment, the double TFT structure is realized by an ion diffusion doping, which saves costs and effectively saves space and optimizes a spatial layout in practical use. The TFT substrate of the embodiment of the present disclosure adopts the double gate structure and forms the TFT channel series structure in the channel region by diffusing and doping the hydrogen atoms in the silicon nitride layer to reduce the impedance of both sides of the channel, short the channel length, improve the electron mobility, and reduce the power consumption. Without changing the yellow light processing equipment, the double TFT structure is realized by the ion diffusion doping, which saves costs and effectively saves space and optimizes a spatial layout in practical use.

As mentioned above, for those of ordinary skill in the art, various corresponding changes and variations may be made according to the technical solution and technical conception of the present disclosure, and all these changes and variations are within the scope of the claims of the present disclosure.

What is claimed is:

1. A method of manufacturing a thin film transistor (TFT) substrate, comprising:
a step S1 of providing a substrate, forming a first gate and a second gate spaced apart from each other on the substrate, depositing a gate insulating layer on the first gate, the second gate, and the substrate, and depositing and patterning to form an active layer on the gate insulating layer and corresponding to the first gate and the second gate;
a step S2 of depositing an etch stop layer on the active layer and the gate insulating layer, the etch stop layer comprising a silicon nitride layer, when depositing the silicon nitride layer of the etch stop layer, hydrogen atoms in the silicon nitride layer diffuse into the active layer, so as to reduce impedance of the active layer; and
a step S3 of depositing and patterning to form a source and a drain on the etch stop layer.

2. The method according to claim 1, wherein in the step S2, the silicon nitride layer of the etch stop layer is deposited by a plasma chemical vapor deposition.

3. The method according to claim 1, wherein in the step S1, the active layer is deposited by electroplating and splashing, and a material of the active layer comprises a metal oxide semiconductor.

4. The method according to claim 1, wherein the step S1 further comprises performing a plasma doping treatment on both sides of the active layer, such that a conductivity on the both sides of the active layer is enhanced to form a source contact region and a drain contact region at both ends of the active layer, and a region between the source contact region and the drain contact region is formed as a channel region;
the step S2 further comprises patterning the etch stop layer, and the etch stop layer forms a first via and a second via respectively over the source contact region and the drain contact region of the active layer; and
in the step S3, the source and the drain contact the source contact region and the drain contact region through the first via and the second via respectively.

5. The method according to claim 1, wherein the etch stop layer further comprises a silicon oxide layer between the silicon nitride layer and the active layer.

6. The method according to claim 1, wherein when the TFT substrate is in use, voltages on the first gate and the second gate are independently controlled.

7. A thin film transistor (TFT) substrate, comprising: a substrate, a first gate, and a second gate spaced apart from each other on the substrate, a gate insulating layer on the first gate, the second gate, and the substrate, an active layer disposed on the gate insulating layer and corresponding to the first gate and the second gate, an etch stop layer disposed on the active layer, and a source and a drain disposed on the etch stop layer;
wherein the etch stop layer comprises a silicon nitride layer, and hydrogen atoms in the silicon nitride layer diffuse into the active layer, so as to reduce impedance of the active layer.

8. The TFT substrate according to claim 7, wherein a material of the active layer comprises a metal oxide semiconductor;
both sides of the active layer are respectively a source contact region and a drain contact region which are enhanced in a conductivity by a plasma doping treatment, and a region between the source contact region and the drain contact region is formed as a channel region; and
the etch stop layer is respectively provided with a first via and a second via respectively over the source contact region and the drain contact region of the active layer, and the source and the drain contact the source contact region and the drain contact region through the first via and the second via respectively.

9. The TFT substrate according to claim 7, wherein the etch stop layer further comprises a silicon oxide layer between the silicon nitride layer and the active layer.

10. The TFT substrate according to claim 7, wherein when the TFT substrate is in use, voltages on the first gate and the second gate are independently controlled.
